(19) United States
(12) Patent Application Publication
(10) Pub. No.: US 2008/0309221 A1
(43) Pub. Date: Dec. 18, 2008

(54) Containment Structure For an Electronic Device

(75) Inventors: Charles D Lang, Goleta, CA (US); Stephan Claude De La Veaux, Wilmington, DE (US); Paul Anthony Sant, Santa Barbara, CA (US); Dennis Damon Walker, Santa Barbara, CA (US); Stephen Sorich, Goleta, CA (US); Matthew Stainer, Goleta, CA (US)

Correspondence Address: WOODCOCK WASHBURN LLP, CIRA CENTRE, 12TH FLOOR, 2929 ARCH STREET, PHILADELPHIA, PA, 19104-2891, US

(73) Assignee: E.I. DU PONT DE NEMOURS AND COMPANY, WILMINGTON, DE (US)

(21) Appl. No.: 11/721,501

(22) PCT Filed: Dec. 29, 2005
(86) PCT No.: PCT/US05/47672

§ 371 Date: Mar. 26, 2008

Related U.S. Application Data
(60) Provisional application No. 60/640,557, filed on Dec. 30, 2004.
(60) Provisional application No. 60/694,876, filed on Jun. 28, 2005.

(51) Int. Cl. H01J 1/62

(52) U.S. Cl. 313/504

(57) ABSTRACT

In one embodiment, a containment structure (230) for an organic composition (240) is provided. The containment structure (230) includes an undercut layer (210) and an overlying layer (220), wherein the undercut (210) and overlying (220) layers define a volume for receiving the organic composition (240) in liquid form.

### CROSS REFERENCE

This application claims benefit to U.S. Provisional Application Ser. Nos. 60/640,557, filed Dec. 30, 2004, and 60/694,876, filed Jun. 28, 2005, the disclosures of which are each incorporated herein by reference in their entireties.

### FIELD

This disclosure relates generally to organic electronic devices, and more particularly to an organic electronic device having an ink containment well, and materials and methods for fabrication of the same.

### BACKGROUND

Organic electronic devices convert electrical energy into radiation, detect signals through electronic processes, convert radiation into electrical energy, or include one or more organic semiconductor layers. When fabricating an organic electronic device from liquid layers, containment structures may be used to separate pixels or colored sub-pixels. Some conventional pixel containment wells (“wells”) may have a surface treatment is used to prevent the applied organic composition from overflowing into neighboring pixels, or from remaining in non-emitting regions where undesirable effects may occur.

In conventional applications where no surface treatment is used, the organic composition typically wets the surface of the well, resulting in a non-uniform final thickness of the dried layer. Additionally, because some organic composition dries and remains on the wall of the well, the thickness of the organic composition in the emitting area at the base of the well depends on the height of the well and the drying conditions. In conventional applications where the well is rendered non-wetting, if the liquid organic composition de-wets from the well while the liquid viscosity is low, the final thickness of the dried organic composition layer is highly non-uniform and the apparent shape may deviate from the desired contained pixel shape.

Thus, what is needed is a containment structure, as well as methods for forming same and an organic electronic device having same, that overcome the above shortcomings and drawbacks.

### SUMMARY

In one embodiment, a containment structure for an organic composition is provided. The containment structure includes an undercut layer and an overlying layer, wherein the undercut and overlying layers define a volume for receiving the organic composition in liquid form.

The foregoing general description and the following detailed description are exemplary and explanatory only and are not restrictive of the invention, as defined in the appended claims.

### BRIEF DESCRIPTION OF THE DRAWINGS

Embodiments are illustrated in the accompanying figures to improve understanding of concepts as presented herein.

FIG. 1 is an exploded view of an exemplary organic electronic device in which aspects of the invention may be implemented;

FIGS. 2A-B are cross-sectional views of a containment structure according to an embodiment of the present invention; and

FIG. 3 is a flowchart illustrating an example organic electronic device fabrication method according to an embodiment of the present invention.

The figures are provided by way of example and are not intended to limit the invention. Skilled artisans appreciate that objects in the figures are illustrated for simplicity and clarity and have not necessarily been drawn to scale. For example, the dimensions of some of the objects in the figures may be exaggerated relative to other objects to help to improve understanding of embodiments.

### DETAILED DESCRIPTION

In one embodiment, a containment structure for an organic composition is provided. The containment structure includes an undercut layer and an overlying layer, wherein the undercut and overlying layers define a volume for receiving the organic composition in liquid form.

In one embodiment, the undercut layer has a first height, and the overlying layer has a second height substantially greater than the first height.

In one embodiment, the first height is predetermined so that a portion of the volume defined by the undercut layer is completely filled with the organic composition after the organic composition has dried.

In one embodiment, the undercut layer is formed from multiple layers of photo-patternable materials having different exposure and development responses.

In one embodiment, surfaces of the undercut layer and the overlying layer that define the volume are rendered non-wetting.

In one embodiment, the volume is defined, at least in part, by a wall of the overlying layer, and the wall is angled to allow wetting of the wall by the liquid composition.

In one embodiment, the wall has a surface treatment that renders the wall non-wetting.

In one embodiment, the overlying layer includes walls that define a portion of the volume, the walls being positively sloped in relation to the undercut layer.

In one embodiment, a method for forming a conducting polymer device is provided. The method includes providing an undercut layer, applying an overlying layer to the undercut layer such that the undercut and overlying layers define a volume for receiving an organic composition in liquid form and introducing the organic composition in liquid form into the volume.

In one embodiment, the volume is defined such that the organic composition, upon drying, completely fills the portion of the volume defined by the undercut layer.

In one embodiment, the undercut layer is provided with a first height, and the overlying layer is applied to have a second height that is substantially greater than the first height.

In one embodiment, the providing step further comprises applying multiple layers of photo-patternable materials having different exposure and development responses.

In one embodiment, the multiple layers of photo-patternable materials are applied by deposition.

In one embodiment, the method further includes rendering surfaces of the undercut layer and the overlying layer that define the volume non-wetting.

In one embodiment, the volume is defined, at least in part, by a wall of the overlying layer, and the wall is angled to allow wetting of the wall by the liquid composition.

In one embodiment, the overlying layer includes walls that define a portion of the volume, the walls being positively sloped in relation to the undercut layer.

In one embodiment, an organic electronic device is provided. The organic electronic device includes an undercut layer having a first height, an overlying layer having a second height that is substantially greater than the first height and wherein the overlying layer is disposed adjacent to the undercut layer, a volume defined by a positively-sloped wall formed in the overlying layer and a surface of the undercut layer and an organic composition that is introduced into the volume when the organic composition is in liquid form.

In one embodiment, a composition including the containment structure described above is provided.

In one embodiment, an organic electronic device having an active layer including the containment structure described above is provided.

In one embodiment, an article useful in the manufacture of an organic electronic device, comprising the containment structure described above is provided.

In one embodiment, compositions are provided comprising the above-described compounds and at least one solvent, processing aid, charge transporting material, or charge blocking material. These compositions can be in any form, including, but not limited to solvents, emulsions, and colloidal dispersions.

### DEFINITIONS

The use of “a” or “an” are employed to describe elements and components of the invention. This is done merely for convenience and to give a general sense of the invention. This description should be read to include one or at least one and the singular also includes the plural unless it is obvious that it is meant otherwise.

The term “active” when referring to a layer or material is intended to mean a layer or material that exhibits electronic or electro-radiative properties. An active layer material may emit radiation or exhibit a change in concentration of electron-hole pairs when receiving radiation. Thus, the term “active material” refers to a material which electronically facilitates the operation of the device. Examples of active materials include, but are not limited to, materials which conduct, inject, transport, or block a charge, where the charge can be either an electron or a hole. Examples of inactive materials include, but are not limited to, planarization materials, insulating materials, and environmental barrier materials.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

The term “layer” is used interchangeably with the term “film” and refers to a coating covering a desired area. The area can be as large as an entire device or a specific functional area such as the actual visual display, or as small as a single sub-pixel. Films can be formed by any conventional deposition technique, including vapor deposition and liquid deposition. Liquid deposition techniques include, but are not limited to, continuous deposition techniques such as spin coating, gravure coating, curtain coating, dip coating, slot-die coating, spray-coating, and continuous nozzle coating; and discontinuous deposition techniques such as ink jet printing, gravure printing, and screen printing.

The term “organic electronic device” is intended to mean a device including one or more semiconductor layers or materials. Organic electronic devices include, but are not limited to: (1) devices that convert electrical energy into radiation (e.g., a light-emitting diode, light emitting diode display, diode laser, or lighting panel), (2) devices that detect signals through electronic processes (e.g., photodetectors photoconductive cells, photoresistors, photoswitches, phototransistors, phototubes, infrared (“IR”) detectors, or biosensors), (3) devices that convert radiation into electrical energy (e.g., a photovoltaic device or solar cell), and (4) devices that include one or more electronic components that include one or more organic semiconductor layers (e.g., a transistor or diode). The term device also includes coating materials for memory storage devices, antistatic films, biosensors, electrochromic devices, solid electrolyte capacitors, energy storage devices such as a rechargeable battery, and electromagnetic shielding applications.

The term “substrate” is intended to mean a workpiece that can be either rigid or flexible and may include one or more layers of one or more materials, which can include, but are not limited to, glass, polymer, metal, or ceramic materials, or combinations thereof.

Unless otherwise defined, all technical and scientific terms used herein have the same meaning as commonly understood by one of ordinary skill in the art to which this invention belongs. Although methods and materials similar or equivalent to those described herein can be used in the practice or testing of embodiments of the present invention, suitable methods and materials are described below. All publications, patent applications, patents, and other references mentioned herein are incorporated by reference in their entirety, unless a particular passage is cited. In case of conflict, the present specification, including definitions, will control. In addition, the materials, methods, and examples are illustrative only and not intended to be limiting.

To the extent not described herein, many details regarding specific materials, processing acts, and circuits are conventional and may be found in textbooks and other sources within the organic light-emitting diode display, photodetector, photovoltaic, and semiconductive member arts.

### EXAMPLES

The concepts described herein will be further described in the following examples, which do not limit the scope of the invention described in the claims.

An embodiment of a containment structure for an organic composition is disclosed herein. The containment structure may be formed by way of a liquid layer application technique used, for example, to fabricate organic electronic devices. For example, the containment structure may be formed so as to have an undercut layer that is substantially shorter than a positively-sloped overlying layer. The containment structure may be formed in connection with an organic electronic device, or any type of conducting polymer device.

Conducting polymer devices, such as organic electronic devices, include, but are not limited to, (1) devices that convert electrical energy into radiation (e.g., a light-emitting diode, light emitting diode display, or diode laser), (2) devices that detect signals through electronics processes (e.g., photodetectors, photoconducting cells, photoresistors, photoswitches, phototransistors, phototubes, IR detectors), (3) devices that convert radiation into electrical energy, (e.g., a photovoltaic device or solar cell), and (4) devices that include one or more electronic components that include one or more organic semi-conductor layers (e.g., a transistor or diode). Persons of skill in the art should recognize that other organic electronic devices may be elaborated and that additional classes of such devices may arise in the future that may benefit from the present invention. All such devices are contemplated hereby.

Thus, while embodiments of the present invention may be used in connection with any conducting polymer device, it will be appreciated that the discussion herein focuses on organic electronic devices for purposes of explanation and clarity.

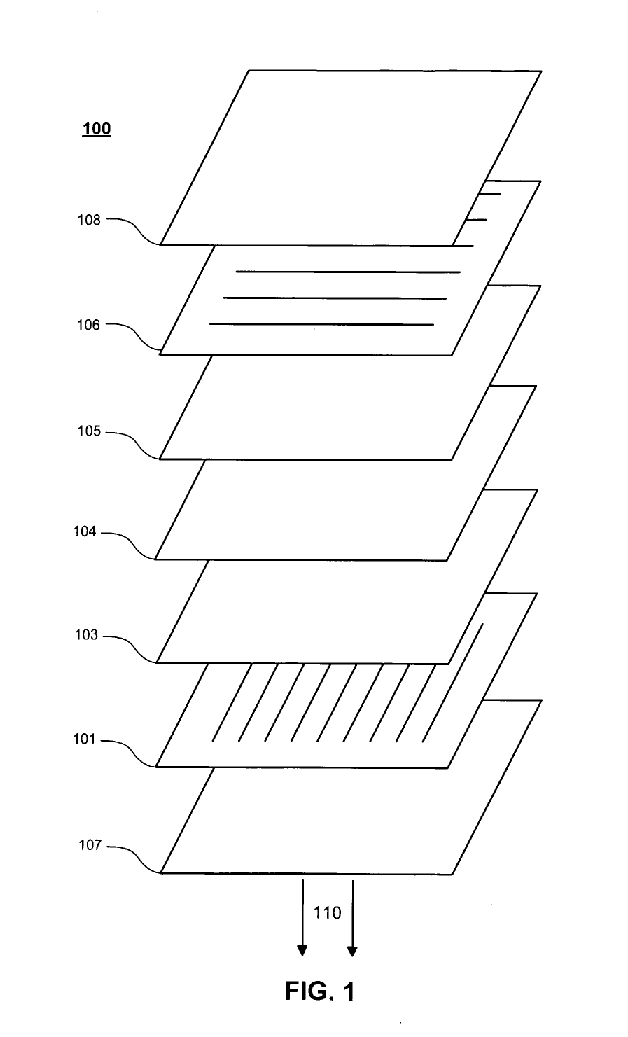

FIG. 1 is an exploded view of an exemplary organic electronic device 100 in which aspects of the invention may be implemented. organic electronic device 100 comprises an anode layer 101, a cathode layer 106 and a photoactive layer 104 that is disposed between anode layer 101 and cathode layer 106. Adjacent to anode layer 101 may be a buffer layer 103 comprising hole transport material. Adjacent to cathode layer 106 may be an electron transport layer 105 comprising an electron transport material. Electron transport layer 105 itself may be comprised of one or more layers. For example, electron transport layer 105 may include an electron transport layer and a layer formed from a low work function material. The electron transport layer may be formed from, for example, BAlq3, Alq3 or the like. The low work function layer may be formed from, for example, calcium, barium, lithium fluoride, etc.

Depending upon the application of device 100, photoactive layer 104 can be a light-emitting layer that is activated by an applied voltage (such as in a light-emitting diode or light-emitting electrochemical cell), a layer of material that responds to radiant energy and generates a signal with or without an applied bias voltage (such as in a photodetector). Examples of photodetectors include photoconducting cells, photoresistors, photoswitches, phototransistors, and phototubes, and photovoltaic cells, as these terms are described in Markus, John, Electronics and Nucleonics Dictionary, 470 and 476 (McGraw Hill, Inc. 1966). Hermetic package 108 serves to protect device 100, and in particular photoactive layer 104 and cathode layer 106, and may be fabricated from any material suitable for such a purpose.

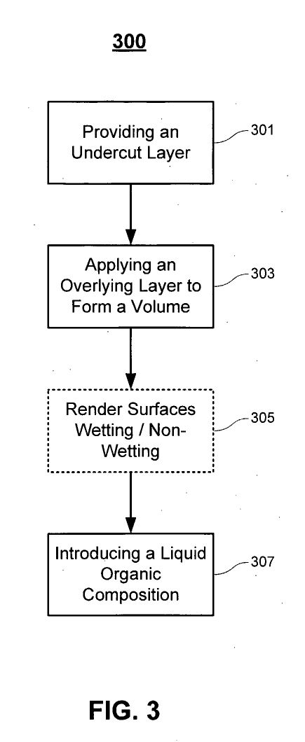

Other layers in device 100 can be made of any materials which are known to be useful in such layers, upon consideration of the function to be served by such layers. Anode layer 101 comprises an electrode that is effective for injecting positive charge carriers. Anode layer 101 can be made of, for example, materials containing or comprising metal, mixed metals, alloy, metal oxides or mixed-metal oxide. Anode layer 101 may comprise a conducting polymer, polymer blend or polymer mixtures. Suitable metals include the Group 11 metals, the metals in Groups 4, 5, and 6, and the Group 8, 10 transition metals. If anode 101 is to be light-transmitting, mixed-metal oxides of Groups 12, 13 and 14 metals, such as indium-tin-oxide (ITO), are generally used. Anode 101 may also comprise an organic material, especially a conducting polymer such as polyaniline, including exemplary materials as described in “Flexible Light-Emitting Diodes Made From Soluble Conducting Polymer,” Nature, vol. 357, pp. 477-479 (Jun. 11, 1992). It will be appreciated that anodes 101 may be deposited onto substrate 107 as will be discussed below in connection with FIG. 3. When the electrodes of anode layer 101 and cathode layer 106 are energized, light 110 is emitted from device 100. Accordingly, at least one of the anode 101 and cathode 106 should be at least partially transparent to allow the generated light to be observed. In addition, substrate 107 should also be at least partially transparent for the same reason.

Examples of hole transport materials for layer 120 have been summarized for example, in Kirk-Othmer Encyclopedia of Chemical Technology, Fourth Edition, Vol. 18, p. 837-860, 1996, by Y. Wang. Both hole transporting molecules and polymers can be used. Commonly used hole transporting molecules include, but are not limited to: N,N′-diphenyl-N,N′-bis(3-methylphenyl)-[1,1′-biphenyl]-4,4′-diamine (TPD), 1,1-bis[(di-4-tolylamino) phenyl]cyclohexane (TAPC), N,N′-bis(4-methylphenyl)-N,N′-bis(4-ethylphenyl)-[1,1′-(3,3′-dimethyl)biphenyl]-4,4′-diamine (ETPD), tetrakis-(3-methylphenyl)-N,N,N′,N′-2,5-phenylenediamine (PDA), a-phenyl-4-N,N-diphenylaminostyrene (TPS), p-(diethylamino)-benzaldehyde diphenylhydrazone (DEH), triphenylamine (TPA), bis[4-(N,N-diethylamino)-2-methylphenyl](4-methylphenyl)methane (MPMP), 1-phenyl-3-[p-(diethylamino)styryl]-5-[p-(diethylamino)phenyl]pyrazoline (PPR or DEASP), 1,2-trans-bis(9H-carbazol-9-yl)cyclobutane (DCZB), N,N,N′,N′-tetrakis(4-methylphenyl)-(1,1′-biphenyl)-4,4′-diamine (TTB), N,N′-Bis(naphthalen-1-yl)-N,N′-bis-(phenyl)benzidine (α-NPB), and porphyrinic compounds, such as copper phthalocyanine. Commonly used hole transporting polymers include, but are not limited to, polyvinylcarbazole, (phenylmethyl)polysilane, poly(dioxythiophenes), and polyaniline. It is also possible to obtain hole transporting polymers by doping hole transporting molecules such as those mentioned above into polymers such as polystyrene and polycarbonate.

Any organic electroluminescent (“EL”) material can be used in the displays of the invention, including, but not limited to, small molecule organic fluorescent compounds, fluorescent and phosphorescent metal complexes, conjugated polymers, and mixtures thereof. Examples of fluorescent compounds include, but are not limited to, pyrene, perylene, rubrene, coumarin, derivatives thereof, and mixtures thereof. Examples of metal complexes include, but are not limited to, metal chelated oxinoid compounds, such as tris(8-hydroxyquinolato)aluminum (Alq3); cyclometalated iridium and platinum electroluminescent compounds, such as complexes of iridium with phenylpyridine, phenylquinoline, or phenylpyrimidine ligands as disclosed in Petrov et al., U.S. Pat. No. 6,670,645 and Published PCT Applications WO 03/063555 and WO 2004/016710, and organometallic complexes described in, for example, Published PCT Applications WO 03/008424, WO 03/091688, and WO 03/040257, and mixtures thereof. Electroluminescent emissive layers comprising a charge carrying host material and a metal complex have been described by Thompson et al., in U.S. Pat. No. 6,303,238, and by Burrows and Thompson in published PCT applications WO 00/70655 and WO 01/41512. Examples of conjugated polymers include, but are not limited to poly(phenylenevinylenes), polyfluorenes, poly(spirobifluorenes), polythiophenes, poly(p-phenylenes), copolymers thereof, and mixtures thereof.

In one embodiment of the devices of the invention, the photoactive material can be an organometallic complex. In another embodiment, the photoactive material is a cyclometalated complex of iridium or platinum. Other useful photoactive materials may be employed as well. Complexes of Iridium with phenylpyridine, phenylquinoline, or phenylpyrimidine ligands have been disclosed as electroluminescent compounds in Petrov et al., Published PCT Application WO 02/02714. Other organometallic complexes have been described in, for example, published applications US 2001/0019782, EP 1191612, WO 02/15645 and EP 1191614. Electroluminescent devices with an active layer of polyvinyl carbazole (PVK) doped with metallic complexes of iridium have been described by Burrows and Thompson in published PCT applications WO 00/70655 and WO 01/41512. Electroluminescent emissive layers comprising a charge carrying host material and a phosphorescent platinum complex have been described by Thompson et al., in U.S. Pat. No. 6,303,238, Bradley et al., in Synth. Met. (2001), 116 (1-3), 379-383, and Campbell et al., in Phys. Rev. B, Vol. 65 085210.

Examples of electron transport materials which can be used, for example, in electron transport layer 105, cathode layer 106, or otherwise include compounds of embodiments of the invention. Such layers can optionally contain a polymer. Other suitable materials include metal chelated oxinoid compounds, such as tris(8-hydroxyquinolato)aluminum (Alq3); and azole compounds such as 2 (4-biphenylyl)-5-(4-t-butylphenyl)-1,3,4-oxadiazole (PBD) and 3 (4-biphenylyl)-4-phenyl-5-(4-t-butylphenyl)-1,2,4-triazole (TAZ); phenanthrolines such as 4,7-diphenyl-1,10-phenanthroline (DPA) and 2,9-dimethyl-4,7-diphenyl-1,10-phenanthroline (DDPA); and mixtures thereof.

Cathode layer 107 comprises an electrode that is effective for injecting electrons or negative charge carriers. Cathode 107 may be any metal or nonmetal having a lower work function than anode 101. Exemplary materials for cathode 107 can include alkali metals, especially lithium; the Group 2 (alkaline earth) metals; the Group 12 metals, including the rare earth elements and lanthanides; and the actinides. Materials such as aluminum, indium, calcium, barium, samarium and magnesium, as well as combinations, can be used. Li-containing and other compounds, such as LiF and Li₂O, may also be deposited between an organic layer and the cathode layer to lower the operating voltage of the system.

It is known to have other useful layers in organic electronic devices. For example, there can be a layer (not shown) between anode 101 and buffer layer 103 to facilitate positive charge transport and/or band-gap matching of the layers, or to function as a protective layer. Other layers that are known in the art or otherwise may be used. In addition, any of the above-described layers may comprise two or more sub-layers or may form a laminar structure. Alternatively, some or all of anode layer 101, buffer layer 103, photoactive layer 104, electron transport layer 105, cathode layer 106, and other layers may be treated, especially surface treated, to increase charge carrier transport efficiency or other physical properties of the devices. The choice of materials for each of the component layers is preferably determined by balancing the goals of high device efficiency against operational lifetime considerations, fabrication time and complexity factors, and other considerations appreciated by persons skilled in the art. It will be appreciated that determining optimal components, component configurations and compositional identities will be within the knowledge of one of ordinary skill in the art.

An embodiment of the invention can employ liquid deposition using appropriate solvents for sequentially depositing the individual layers on a suitable substrate 107. Substrates such as glass and polymeric films can be used. The liquid can be in the form of solutions, dispersions or emulsions. Typical liquid deposition techniques include, but are not limited to, continuous deposition techniques such as spin coating, gravure coating, curtain coating, dip coating, slot-die coating, spray-coating, and continuous nozzle coating; and discontinuous deposition techniques such as ink jet printing, gravure printing, and screen printing, any conventional coating or printing technique, including but not limited to spin-coating, dip-coating, roll-to-roll techniques, ink-jet printing, screen-printing, gravure printing and the like.

The location of the electron-hole recombination zone in device 100, and thus the emission spectrum of device 100, can be affected by the relative thickness of each layer. Thus the thickness of electron-transport layer 105 should be chosen so that the electron-hole recombination zone is in a light-emitting layer. The desired ratio of layer thicknesses will depend on the exact nature of the materials used.

As noted above, example organic electronic device 100 discussed in connection with FIG. 1 is merely illustrative, as an organic electronic device may be configured in any manner while remaining consistent with an embodiment of the invention. In some organic electronic devices, called active matrix organic electronic device displays, individual deposits of photoactive organic films may be independently excited by the passage of current, leading to individual pixels of light emission. In other organic electronic devices, called passive matrix organic electronic device displays, deposits of photoactive organic films may be excited by rows and columns of electrical contact layers.

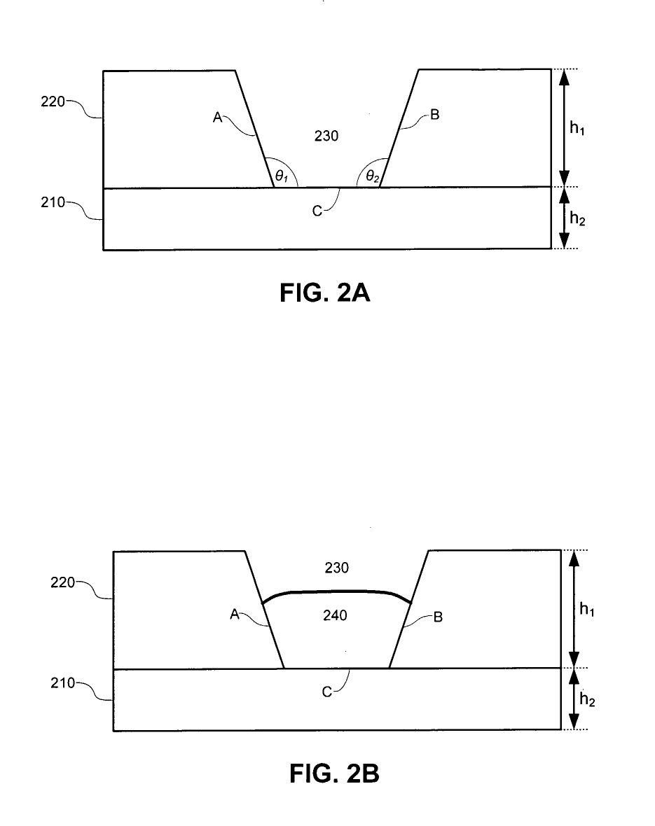

As discussed above, pixels of an organic electronic device display or the like may be separated by containment structures, which are also known as “wells.” FIG. 2A is a cross-sectional view of an exemplary containment structure 230 in which aspects of the invention may be implemented. Containment structure 230 is formed by an undercut layer 210, and an overlying layer 220. It will be appreciated that any of layers 101-108 discussed above in connection with FIG. 1 may be used as either undercut layer 210 and/or overlying layer 220. Undercut layer 210 and overlying layer 220 define containment structure 230, which is a volume for receiving an active organic composition (not shown in FIG. 2A) in liquid form.

In an embodiment, the shape of containment structure 230 is achieved by depositing multiple layers of photo-patternable materials (e.g., positive or negative working photoresist or the like) with different exposure and development responses to provide a relatively short undercut structure, as described in commonly-assigned U.S. patent application Ser. No. 10/910,496, filed Aug. 3, 2004, the contents of which is incorporated by reference herein in its entirety. In addition, one possible embodiment includes a relatively tall overlying layer 220. The overlying layer 220 defines walls A-B that, in conjunction with floor C that is formed from a surface of undercut layer 210, define containment structure 230. The walls A-B may be “positively-sloped.” That is, walls A-B of overlying layer 220 become generally further apart as a distance from floor C of undercut layer 210 increases.

It will be appreciated that walls A-B correspond to the cross-sectional view illustrated in FIGS. 2A-B. In reality, containment structure 230 may take any three-dimensional form such as, for example, an inverted frustoconical shape. In such a configuration, therefore, containment structure 230 may be comprised of a single side, or of any number of sides in addition to or in place of floor C and walls A-B as shown in FIGS. 2A-B. As shown in FIG. 2A, wall A and floor C form angle θ₁. Likewise, wall B and floor C form angle θ₂. In some embodiments, such as in an embodiment discussed above in which containment structure 230 is formed in an inverted frustoconical shape, θ₁ and θ₂ will be substantially equal. Thus, the term “positively-sloped” may also refer to values of θ₁ and θ₂ that exceed 90 degrees.

It can also be seen that height h₁ of overlying layer 220 is substantially greater than height h₂ of undercut layer 210. Thus, an organic composition deposited in containment structure 230 will be contained while realizing the beneficial effects of undercut layer 210.

An embodiment provides that any of walls A-B and/or floor C may be rendered wetting or non-wetting, in order to optimize containment structure 230 for its intended application. For example, such walls A-B and/or floor C may be so modified so as to enable containment structure 230 to receive an active organic composition with minimal organic composition spillage outside of containment structure 230, and while encouraging drying that results in a regular, smooth surface of the organic composition. In one such embodiment, all walls A-B of containment structure 230, excluding floor C, may be rendered non-wetting. “Non-wetting” refers to the contact angle of the liquid organic composition being greater than 45 degrees, and in one embodiment greater than 90 degrees. Means of achieving such a non-wetting state include, for example, treatment with a CF4 plasma. In other embodiments, however, the containment structure 230, including floor C of containment structure 230, remains wettable by the organic composition.

Referring now to FIG. 2B, it can be seen that undercut layer 210 provides spreading of the active organic composition 240 to the base of walls A-B of containment structure 230. The angles formed by walls A-B and floor C (such as angles θ₁ and θ₂ discussed above in connection with FIG. 2A) may be chosen, in an embodiment, to allow wetting by organic composition 240 within containment structure 230, even if walls A and B have received surface treatment to be inherently non-wetting (as discussed above). In one possible embodiment, the height h₂ of undercut layer 210 may be chosen to provide a region for the liquid to build up during drying such that at the end of the drying phase the undercut layer 210 portion of containment structure 230 is completely filled with the dried organic composition 240. It will be appreciated that such a configuration restricts the formation of a physical or compositional non-uniformity, a void, or the like that may impair device performance when subsequent layers are applied such as, for example, by printing or vapor deposition. Thus, it will also be appreciated that height h₂ of undercut layer 210 may be selected so as to have such effects for a variety of, for example, organic compositions, layer types, etc.

An example method 300 of fabricating such an organic electronic device according to an embodiment is illustrated in FIG. 3. At step 301, an undercut layer is provided. It will be appreciated that the undercut layer may correspond to any of layers 101-108 discussed above in connection with FIG. 1, and may be provided by way of any type of liquid application process.

At step 303, a overlying layer is applied to the undercut layer so as to form a volume, such as containment structure 230 of FIGS. 2A-B. Any number of steps may take place in connection with step 303. For example, the overlying layer may first be deposited on the undercut layer and allowed to dry. Afterward, the overlying layer may be etched to form the volume. As a result of step 303, therefore, a volume is defined by walls formed within the overlying layer and a floor formed by a surface of the undercut layer.

At optional step 305, portions of the surfaces that define the volume may be rendered wetting or non-wetting. Any number or type of factors may influence whether optional step 305 is carried out and, if carried out, to what extent. For example, some factors may include design considerations pertaining to the ultimate application in which the resulting organic electronic device will be employed. Other considerations may take into account the characteristics of the organic composition that will be deposited in the volume. In addition, the characteristics of the overlying and undercut layer materials may also be considered. Thus, any number and type of considerations may affect the decision to render a particular surface wetting or non-wetting.

At step 307, a liquid organic composition is introduced into the volume formed by the undercut and overlying layer, and ultimately allowed to dry. Any number of additional processing steps may be employed in connection with the method of FIG. 3. For example, an organic electronic device fabricated according to method 300 may have any or all of layers 101-108 discussed above in connection with example organic electronic device 100 of FIG. 1.

In the foregoing specification, the concepts have been described with reference to specific embodiments. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of invention.

Many aspects and embodiments have been described above and are merely exemplary and not limiting. After reading this specification, skilled artisans appreciate that other aspects and embodiments are possible without departing from the scope of the invention.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

It is to be appreciated that certain features are, for clarity, described herein in the context of separate embodiments, may also be provided in combination in a single embodiment. Conversely, various features that are, for brevity, described in the context of a single embodiment, may also be provided separately or in any subcombination. Further, reference to values stated in ranges include each and every value within that range.

1. A containment structure for an organic composition, comprising:
an undercut layer; and
an overlying layer, wherein the undercut and overlying layers define a volume for receiving the organic composition in liquid form.

2. The containment structure of claim 1, wherein the undercut layer has a first height, and the overlying layer has a second height substantially greater than the first height.

3. The containment structure of claim 2, wherein the first height is predetermined so that a portion of the volume defined by the undercut layer is completely filled with the organic composition after the organic composition has dried.

4. The containment structure of claim 1, wherein the undercut layer is formed from multiple layers of photo-patternable materials having different exposure and development responses.

5. The containment structure of claim 1, wherein surfaces of the undercut layer and the overlying layer that define the volume are rendered non-wetting.

6. The containment structure of claim 1, wherein the volume is defined, at least in part, by a wall of the overlying layer, and the wall is angled to allow wetting of the wall by the liquid composition.

7. The containment structure of claim 6, wherein the wall has a surface treatment that renders the wall non-wetting.

8. The containment structure of claim 1, wherein the overlying layer includes walls that define a portion of the volume, the walls being positively sloped in relation to the undercut layer.

9. A method for forming a conducting polymer device, comprising:
providing an undercut layer;
applying an overlying layer to the undercut layer such that the undercut and overlying layers define a volume for receiving an organic composition in liquid form; and
introducing the organic composition in liquid form into the volume.

10. The method of claim 9, wherein the volume is defined such that the organic composition, upon drying, completely fills the portion of the volume defined by the undercut layer.

11. The method of claim 9, wherein the undercut layer is provided with a first height, and the overlying layer is applied to have a second height that is substantially greater than the first height.

12. The method of claim 9, wherein said providing step further comprises applying multiple layers of photo-patternable materials having different exposure and development responses.

13. The method of claim 12, wherein the multiple layers of photo-patternable materials are applied by deposition.

14. The method of claim 9, further comprising rendering surfaces of the undercut layer and the overlying layer that define the volume non-wetting.

15. The method of claim 9, wherein the volume is defined, at least in part, by a wall of the overlying layer, and the wall is angled to allow wetting of the wall by the liquid composition.

16. The method of claim 9, wherein the overlying layer includes walls that define a portion of the volume, the walls being positively sloped in relation to the undercut layer.

17. An organic electronic device, comprising:
an undercut layer having a first height;
an overlying layer having a second height that is substantially greater than the first height and wherein the overlying layer is disposed adjacent to the undercut layer;
a volume defined by a positively-sloped wall formed in the overlying layer and a surface of the undercut layer; and
an organic composition that is introduced into the volume when the organic composition is in liquid form.

18. A composition including the containment structure of claim 1.

19. An organic electronic device having an active layer including the containment structure of claim 1.

20. An article useful in the manufacture of an organic electronic device, comprising the containment structure of claim 1.
